(19) United States
(12) Patent Application Publication
(10) Pub. No.: US 2012/0109556 A1
(43) Pub. Date: May 3, 2012

(54) BAND SELECT STATE OF CHARGE WEIGHTED SCALING METHOD

(75) Inventors: Asif A. Syed, Canton, MI (US); Brian J. Koch, Berkley, MI (US); Sascha Schaefer, Selters (DE); Andreas Koenekamp, Darmstadt (DE)

(73) Assignee: GM GLOBAL TECHNOLOGY OPERATIONS LLC, DETROIT, MI (US)

(21) Appl. No.: 13/028,860

(22) Filed: Feb. 16, 2011

Related U.S. Application Data
(60) Provisional application No. 61/408,477, filed on Oct. 29, 2010.

(51) Int. Cl. G01R 31/36

(52) U.S. Cl. 702/63

(57) ABSTRACT

A method and system for selectively using a voltage-based state of charge estimate in an overall state of charge calculation. Regions or bands of battery pack state of charge are established, where in some regions, open circuit voltage is known to be a good indicator of state of charge, and in other regions, open circuit voltage is known to be a poor indicator of state of charge due to a high sensitivity to measurement error. In regions or bands where voltage-based state of charge is expected to be accurate, the voltage-based state of charge estimate may be used to scale or adjust a current-based state of charge estimate, thus avoiding a continuous accumulation of error in the current-based estimate. In regions or bands where voltage-based state of charge is known to be prone to error, only current-based state of charge information is used.

### CROSS-REFERENCE TO RELATED APPLICATIONS

This application claims the benefit of the priority date of U.S. Provisional Patent Application Ser. No. 61/408,477, titled Band Select State of Charge Weighted Scaling Method, filed Oct. 29, 2010.

### BACKGROUND OF THE INVENTION

1. Field of the Invention

This invention relates generally to state of charge measurement in a battery pack and, more particularly, to a method for improving the fidelity of state of charge measurement in a vehicle battery pack which establishes bands of state of charge, and applies a band-specific scaling factor to voltage-based state of charge to obtain a more accurate overall measurement of state of charge.

2. Discussion of the Related Art

Electric vehicles and gasoline-electric hybrid vehicles are rapidly gaining popularity in today's automotive marketplace. Electric and hybrid vehicles offer several desirable features, such as reducing or eliminating emissions and petroleum-based fuel consumption at the consumer level, and potentially lower operating costs. A key component of electric and hybrid vehicles is the battery pack, which can represent a substantial proportion of the vehicle's cost. Battery packs in these vehicles typically consist of numerous interconnected cells, which are able to deliver a lot of power on demand. Maximizing battery pack performance and life are key considerations in the design and operation of electric and hybrid vehicles.

In order to maximize battery pack durability and provide useful range information to a driver of the vehicle, it is important to be able to accurately measure the state of charge of the battery pack in an electric or hybrid vehicle. A common method of estimating the state of charge of the battery pack is by measuring the open circuit or no load voltage across the battery pack. The open circuit voltage measurement is easy to make, but unfortunately may be prone to error. Open circuit voltage error may be introduced by a voltage sensor itself, by a voltage sensing circuit in a controller, by sizing of electronics hardware, ND converters, or filter gains, or by combinations of these and other factors. Compounding the voltage measurement error is the fact that, in some regions of battery pack state of charge, the actual state of charge is extremely sensitive to small changes in open circuit voltage. In other words, a small open circuit voltage measurement error can make a big difference in the estimated state of charge of the battery pack. This can result in erroneous estimations of the remaining battery power driving range of the vehicle, and can also lead to over-charging or over-discharging of the battery pack.

There is a need for a battery pack state of charge measurement methodology which recognizes when open circuit voltage can be used as an accurate indicator of battery pack state of charge, and when other indicators should be given more weight in estimating battery pack state of charge. Such a method could increase customer satisfaction through improved battery pack life and more consistent depiction of vehicle battery power driving range.

### SUMMARY OF THE INVENTION

In accordance with the teachings of the present invention, a method and system are disclosed for selectively using a voltage-based state of charge estimate in an overall state of charge calculation. Regions or bands of battery pack state of charge are established, where in some regions, open circuit voltage is known to be a good indicator of state of charge, and in other regions, open circuit voltage is known to be a poor indicator of state of charge due to a high sensitivity to measurement error. In regions or bands where voltage-based state of charge is expected to be accurate, the voltage-based state of charge estimate may be used to scale or adjust a current-based state of charge estimate, thus avoiding a continuous accumulation of error in the current-based estimate. In regions or bands where voltage-based state of charge is known to be prone to error, only current-based state of charge information is used.

Additional features of the present invention will become apparent from the following description and appended claims, taken in conjunction with the accompanying drawings.

### BRIEF DESCRIPTION OF THE DRAWINGS

FIG. 1 is a schematic diagram of an electric vehicle, battery pack, and associated monitoring and control system;

FIG. 2 is a graph of open circuit voltage versus actual state of charge in a typical electric vehicle battery pack; and

FIG. 3 is a flow chart diagram of a method which can be used to calculate a battery pack's state of charge based on open circuit voltage and other parameters.

### DETAILED DESCRIPTION OF THE EMBODIMENTS

The following discussion of the embodiments of the invention directed to a battery pack state of charge weighted scaling method is merely exemplary in nature, and is in no way intended to limit the invention or its applications or uses. For example, the invention is described below in terms of its application to electric and hybrid vehicles, but the invention may be equally applicable to battery packs for other types of vehicles, such as forklifts and golf carts, and for battery packs in non-vehicle applications.

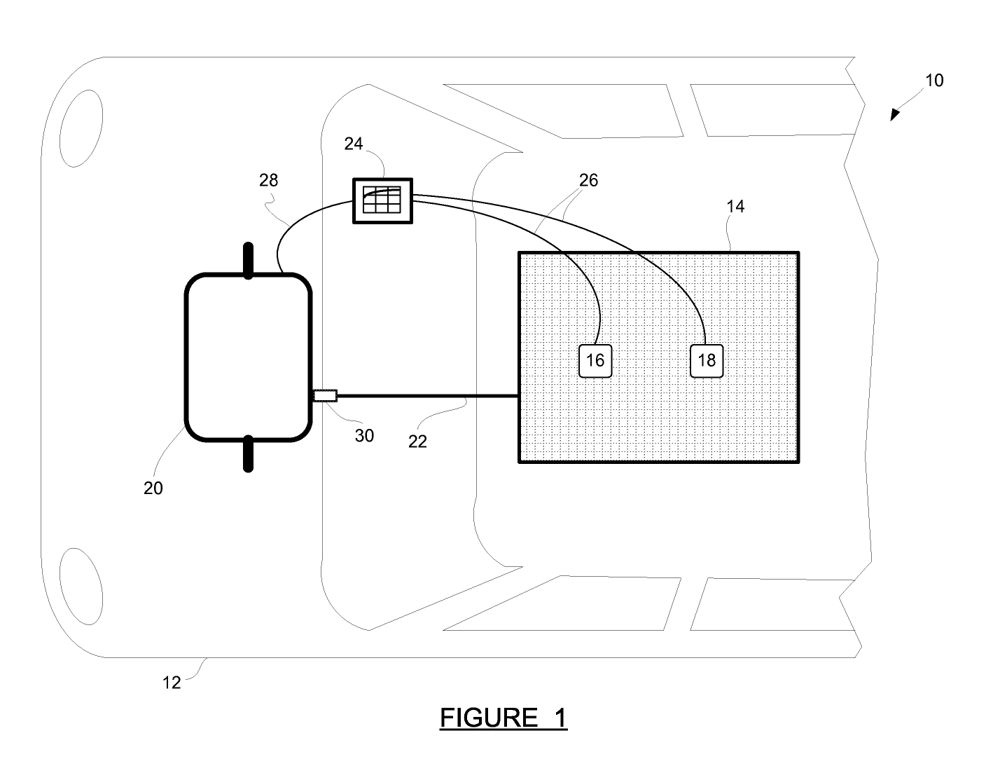

FIG. 1 is a schematic diagram of a power management system 10 in a vehicle 12. A battery pack 14 stores electrical energy for powering the vehicle 12. The battery pack 14 is equipped with a voltage sensor 16 and a temperature sensor 18. In actual implementation, more than one of the voltage sensor 16 and the temperature sensor 18 may be used. The battery pack 14 provides energy to a motor 20, which drives the vehicle's wheels. A power cable 22 delivers the electric current from the battery pack 14 to the motor 20. A controller 24 monitors the voltage and temperature conditions in the battery pack 14, and controls operation of the motor 20. Sensor connections 26, which may be wired or wireless, provide signals from the voltage sensor 16 and the temperature sensor 18 to the controller 24. And a motor connection 28 provides two-way communication between the controller 24 and the motor 20, including control of the operation of the motor 20, and providing data back to the controller 24 from a current sensor 30. The current sensor 30 measures both discharging current drawn by the motor 20, and charging current provided by a charging circuit (not shown).

The vehicle 12 described throughout this disclosure may be a pure plug-in electric vehicle, a fuel cell electric vehicle, a gasoline-electric or diesel-electric hybrid vehicle, or any other type of vehicle which uses a battery pack for some or all of its power. The battery pack 14 may be of a Lithium-Ion type, or some other type. The disclosed methods and systems are particularly useful for any battery chemistry where the relationship between open circuit voltage and state of charge is non-linear.

Knowing the state of charge of the battery pack 14 is important for proper power management. In a pure electric vehicle, a low state of charge must be communicated to the vehicle's driver, so that the battery pack 14 can be plugged in and recharged. In a hybrid vehicle, a low state of charge will trigger the start-up of an engine or fuel cell (not shown in FIG. 1) which can recharge the battery pack 14.

Open circuit voltage, measured by the voltage sensor 16, is often used as an indicator of battery pack state of charge, as the open circuit voltage is known to drop as state of charge drops. However, in many types of battery pack chemistry, the relationship between open circuit voltage and state of charge is quite non-linear. As a result, there are some regions or bands of battery pack state of charge in which open circuit voltage is not a good indicator of state of charge. That is because, in these regions, open circuit voltage stays nearly constant over a fairly wide range of state of charge. In the regions where open circuit voltage is not a good indicator of state of charge, it is desirable to use some other measurement to estimate state of charge.

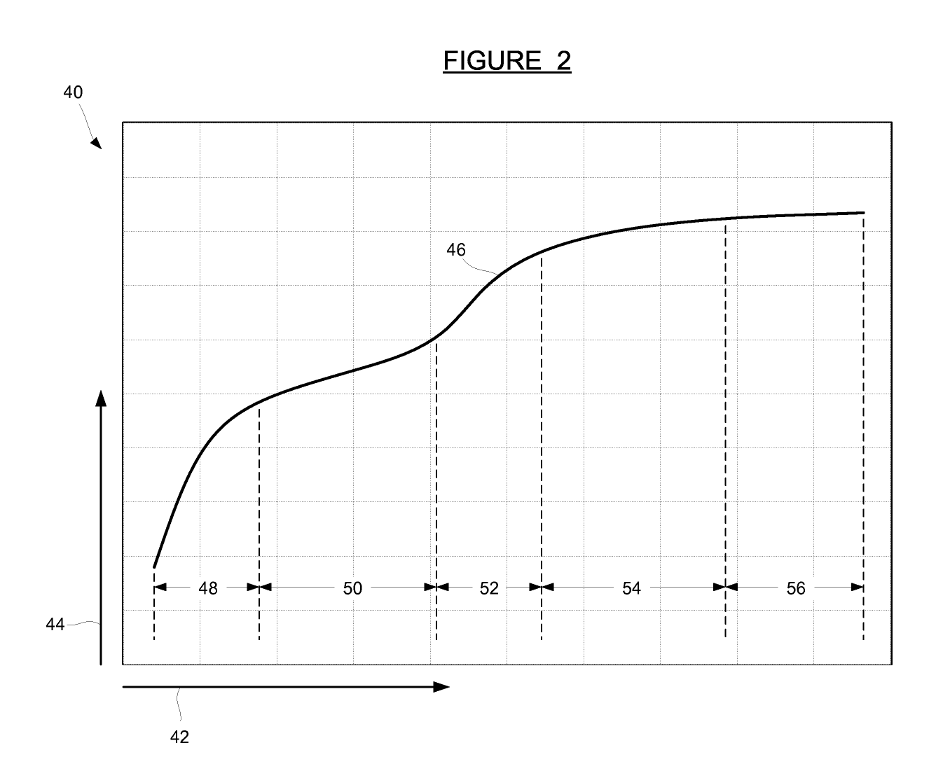

FIG. 2 is a graph 40 which illustrates the situation described above. On the graph 40, horizontal axis 42 depicts state of charge, and vertical axis 44 depicts open circuit voltage for the battery pack 14. Curve 46 exhibits the non-linear characteristic described above. The graph 40 is divided into different regions or bands of state of charge, where the nature of the curve 46 is fairly consistent within each region or band. In region 48, where state of charge is low, it can be seen that the slope of the curve 46 is high; that is, for any incremental change in state of charge, there is a large change in open circuit voltage. Thus, in the region 48, open circuit voltage is a very good indicator of state of charge. In other words, in the region 48, open circuit voltage can measured, and the voltage value can be used to accurately look up the state of charge from the curve 46. In region 50, the slope of the curve 46 is moderate. Thus, in the region 50, open circuit voltage is a fair indicator of state of charge. In region 52, the slope of the curve 46 is again fairly high, and thus open circuit voltage is a good indicator of state of charge in the region 52.

In region 54, however, the slope of the curve 46 is low. That is, there is little change in open circuit voltage over a fairly large range of state of charge. In the region 54, a small measurement error in the value of the open circuit voltage would result in a large error in the estimated state of charge, if open circuit voltage were the only basis for the estimate. Thus, in the region 54, open circuit voltage is not a good indicator of state of charge. In region 56, the slope of the curve 46 is very low, such that there is very little change in open circuit voltage across the entire range of state of charge. Thus, in the region 56, open circuit voltage is a very poor indicator of state of charge, and some other parameter must be used to accurately estimate the state of charge of the battery pack 14.

Any number of regions can be defined, depending on the shape of the curve 46 and the battery's chemistry for a particular design of the battery pack 14. The curve 46 also changes as a function of the temperature of the battery pack 14. Therefore, the curve 46 must actually be measured at many temperatures across the full range of battery pack temperatures that can be expected in vehicle operation. For any given temperature, a voltage-based state of charge can then be estimated by measuring open circuit voltage and finding the corresponding state of charge from the curve 46.

Battery pack durability is significantly affected by the charging and discharging history of the battery pack 14. In particular, over-charging or over-discharging the battery pack 14 can reduce its life. This fact can be used to illustrate the problem which may stem from erroneously estimating the state of charge. In the region 56, the state of charge is high, so running out of electrical power is not a concern. However, if the battery pack 14 is being charged, and open circuit voltage is used to estimate the state of charge, a large error in state of charge estimation is possible. This could result in ending the recharging operation when the battery pack 14 is much less than fully charged, or it could result in significantly over-charging the battery pack 14. Neither of these results is good. Therefore, it is desirable to use other data, besides open circuit voltage, to estimate battery pack state of charge in the regions 54 and 56.

On the other hand, in the region 48, open circuit voltage is a very good indicator of the battery pack state of charge. Thus, it would be advantageous to use open circuit voltage as a primary indicator of state of charge in some regions, and other data as a primary indicator of state of charge in other regions. This can be accomplished using a weighted function, where the weight factor is established based on what state of charge region or band the battery pack 14 is in. In order to define such a weighted function, a different way of estimating state of charge is needed, besides the voltage-based state of charge estimate described above.

Another common way to estimate the state of charge of the battery pack 14 is to measure the time-integrated flow of current into or out of the battery pack 14, also known as coulomb counting. For example, if the total energy storage capacity of the battery pack 14 is known to be 100 amp-hours, and it is known that the battery pack 14 begins in a fully charged condition, and 50 amp-hours are then discharged to the motor 20, then the battery pack 14 is estimated to be at 50% state of charge based on current draw. Likewise, if the battery pack 14 is fully discharged, then the number of amp-hours of charging can be used to estimate the state of charge of the battery pack 14. This approach, known as current-based state of charge estimating or coulomb counting, can be used as an additional source of information to estimate battery pack state of charge. In fact, a current-based state of charge estimate is often used as the primary source of real-time information about battery pack state of charge. One limitation with this method is drift due to small errors in the current being integrated. Any small noise or error in the measurement of current will result in the state of charge reading drifting up or down over time. Therefore, current-based state of charge estimation cannot reliably be used as the only indicator of state of charge, because error in the time-integrated current will accumulate over time.

Thus, what is needed is a method of using the current-based state of charge estimate, and scaling or refining the current-based estimate with a voltage-based state of charge estimate when appropriate. For this purpose, a weighted function can be established as follows:

SOC=w·SOC_{V}+(1−w)·SOC_{C} (1)

Where SOC is the reported value for state of charge which is used by the controller 24, SOC_{V} is the voltage-based state of charge estimate, SOC_{C} is the current-based state of charge estimate, and w is a weight factor.

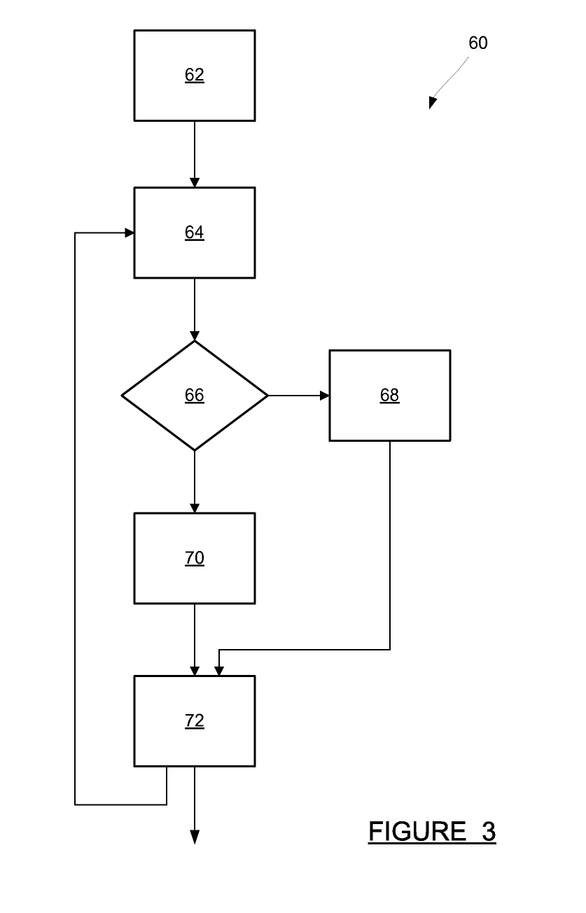

FIG. 3 is a flow chart diagram 60 of a method which can be used for calculating an improved state of charge value, for any region of battery pack operation, using both voltage-based state of charge and current-based state of charge estimates as input. The process begins at box 62, where an open circuit voltage measurement across the battery pack 14 and a temperature measurement in the battery pack 14 are taken. The open circuit voltage is measured by the voltage sensor 16, while the temperature is measured by the temperature sensor 18. Charging or discharging current is also measured at the box 62, and used to estimate the current-based state of charge. Current is measured by the current sensor 30 and time-integrated by the controller 24.

At box 64, a state of charge region or band is determined, based on the measurements from the box 62. At decision diamond 66, it is determined whether certain criteria are met for the region or band which has been identified at the box 64. Criteria may include current exceeding a certain threshold, and state of charge deviation exceeding a certain threshold. For example, consider a case where it is determined at the box 64 that the battery pack 14 is currently in the region 48. First, the current flow measurement from the box 62 is compared to a minimum current threshold. The minimum current threshold is established to ensure that the state of charge in the battery pack 14 is actually changing. If the minimum current threshold is not met, then there is no need to compute a new state of charge. Next, a state of charge deviation is calculated as the difference between the voltage-based state of charge estimate and the current-based state of charge estimate. The state of charge deviation is then compared to a threshold value. Here again, if there is little or no deviation, then there is no need to adjust the current-based state of charge.

If the criteria, such as minimum current and minimum deviation, are met at the decision diamond 66, then a weight factor for the voltage-based state of charge estimate is set at box 68, where the weight factor is chosen based upon the band or region. For example, a weight factor near 1 may be used for the region 48, such that the voltage-based state of charge estimate will be dominant. On the other hand, a weight factor near 0 may be used for the region 56, such that the current-based state of charge estimate will be dominant. If the criteria are not met at the decision diamond 66, then the weight factor is set to zero at box 70. The net effect of this is that the voltage-based state of charge estimate is given a high weight in situations where the voltage-based estimate is expected to be accurate. Thus, in these situations, the voltage-based estimate is a dominant factor in calculating the state of charge value used by the controller 24. Conversely, in situations where voltage-based state of charge is not expected to be a reliable indicator of actual state of charge, or other prerequisite conditions are not met, the voltage-based estimate is given a low or zero weight, and the current-based estimate is dominant.

The values of the minimum current threshold and the minimum deviation threshold for each band, as well as the weight factor for each band, are predetermined for any particular battery pack design. For example, for the region 48, the deviation threshold may be small, meaning that voltage-based state of charge scaling will be applied if there is even a small deviation between the voltage-based and current-based state of charge estimates, since there is a high confidence in the voltage-based state of charge estimate in the region 48. For the same reason, the weight factor for the region 48 will be high. Conversely, the deviation threshold may be large and the weight factor small for the region 56.

At box 72, the reported value for state of charge, SOC, is calculated using Equation (1). For the calculation at the box 72, the weight factor w is established at the box 68 or 70 as described above. The voltage-based state of charge estimate, SOC_{V}, is looked up from the open circuit voltage measurement and the temperature measurement taken at the box 62. The current-based state of charge estimate, SOC_{C}, is updated at each time step by the controller 24 using the current measurement from the current sensor 30. The reported state of charge value, SOC, can be provided from the box 72 back to the box 64 to use as input in determining the state of charge band or region.

The reported state of charge value, SOC, is displayed to the driver of the vehicle 12, so that the driver has the best possible information about the state of charge status of the battery pack 14. The reported state of charge value, SOC, is also used by the controller 24 for control purposes—including issuing a warning to the driver or shutting down the vehicle due to a very low state of charge if no other source of power is available, commencing recharging of the battery pack 14 via an engine-powered generator if available, or ceasing recharging of the battery pack 14 when a fully-charged condition is reached.

By continuously self-correcting the reported state of charge value, over-charging or over-discharging of the battery pack 14 can be avoided, thus resulting in a longer battery pack life. Longer battery pack life, together with more accurate state of charge readings while driving, translate into an improved experience for the owner and driver of the vehicle 12.

The foregoing discussion discloses and describes merely exemplary embodiments of the present invention. One skilled in the art will readily recognize from such discussion and from the accompanying drawings and claims that various changes, modifications and variations can be made therein without departing from the spirit and scope of the invention as defined in the following claims.

What is claimed is:

1. A method for calculating a reported state of charge of a battery pack, said method comprising:
defining a plurality of state of charge bands for the battery pack, where each of the state of charge bands represents a range of state of charge;
measuring open circuit voltage across the battery pack, temperature in the battery pack, and current flow into or out of the battery pack;
estimating a voltage-based state of charge based on the open circuit voltage and the temperature, and estimating a current-based state of charge based on the current flow;
determining a current state of charge band as the state of charge band in which the battery pack currently exists;
checking applicability criteria to determine whether voltage-based state of charge scaling is applicable;
establishing a weight factor for the voltage-based state of charge based on the current state of charge band and the applicability criteria; and
calculating the reported state of charge based on the weight factor, the voltage-based state of charge, and the current-based state of charge.

2. The method of claim 1 wherein estimating a voltage-based state of charge includes interpolating the voltage-based state of charge from a table of the open circuit voltage and the temperature.

3. The method of claim 1 wherein estimating a current-based state of charge includes incrementally calculating the current-based state of charge by adding the current flow multiplied by a time step to a previous state of charge value, where the current flow is negative for discharging current.

4. The method of claim 1 wherein checking applicability criteria to determine whether voltage-based state of charge scaling is applicable includes comparing the current flow to a minimum current threshold and comparing a deviation between the voltage-based state of charge and the current-based state of charge to a minimum deviation threshold.

5. The method of claim 1 wherein establishing a weight factor for the voltage-based state of charge includes using a higher weight factor for state of charge bands where the rate of change of open circuit voltage with respect to state of charge is high.

6. The method of claim 1 wherein establishing a weight factor for the voltage-based state of charge includes setting the weight factor to zero when the applicability criteria are not met.

7. The method of claim 1 wherein calculating the reported state of charge includes using the equation:
SOC=w·SOC_{V}+(1−w)·SOC_{C}
where SOC is the reported state of charge, SOC_{V} is the voltage-based state of charge, SOC_{C} is the current-based state of charge, and w is the weight factor.

8. The method of claim 1 wherein the battery pack provides power to a motor which is used to drive a vehicle.

9. The method of claim 8 further comprising using the reported state of charge of the battery pack to control operation of the vehicle, the motor, or the battery pack.

10. A method for calculating a reported state of charge of a battery pack in a vehicle powered by an electric motor, said method comprising:
defining a plurality of state of charge bands for the battery pack, where each of the state of charge bands represents a range of state of charge;
measuring open circuit voltage across the battery pack, temperature in the battery pack, and current flow into or out of the battery pack;
estimating a voltage-based state of charge based on the open circuit voltage and the temperature, and estimating a current-based state of charge based on the current flow;
determining a current state of charge band as the state of charge band in which the battery pack currently exists;
checking applicability criteria to determine whether voltage-based state of charge scaling is applicable, where the applicability criteria include comparing the current flow to a minimum current threshold and comparing a deviation between the voltage-based state of charge and the current-based state of charge to a minimum deviation threshold;
establishing a weight factor for the voltage-based state of charge based on the current state of charge band and the applicability criteria; and
calculating the reported state of charge based on the weight factor, the voltage-based state of charge, and the current-based state of charge.

11. The method of claim 10 wherein estimating a voltage-based state of charge includes interpolating the voltage-based state of charge from a table of the open circuit voltage and the temperature, and estimating a current-based state of charge includes incrementally calculating the current-based state of charge by adding the current flow multiplied by a time step to a previous state of charge value, where the current flow is negative for discharging current.

12. The method of claim 10 wherein establishing a weight factor for the voltage-based state of charge includes using a higher weight factor for state of charge bands where the rate of change of open circuit voltage with respect to state of charge is high, and setting the weight factor to zero when the applicability criteria are not met.

13. The method of claim 10 further comprising using the reported state of charge of the battery pack to control operation of the vehicle, the motor, or the battery pack.

14. A power management system for a battery pack, said power management system comprising:
a voltage sensor for measuring open circuit voltage of the battery pack;
a temperature sensor for measuring a temperature of the battery pack;
a current sensor for measuring electrical current into or out of the battery pack; and
a controller in communication with the voltage sensor, the temperature sensor, and the current sensor, said controller being configured to estimate a voltage-based state of charge and a current-based state of charge, determine a state of charge band in which the battery pack currently exists, establish a weight factor for the voltage-based state of charge, and calculate a reported state of charge value.

15. The power management system of claim 14 wherein the controller estimates the voltage-based state of charge based on the open circuit voltage of the battery pack and the temperature of the battery pack.

16. The power management system of claim 14 wherein the controller establishes the weight factor for the voltage-based state of charge based on the state of charge band and pre-determined applicability criteria.

17. The power management system of claim 16 wherein the pre-determined applicability criteria include the electrical current exceeding a minimum current threshold and a deviation between the voltage-based state of charge and the current-based state of charge exceeding a minimum deviation threshold.

18. The power management system of claim 14 wherein the controller calculates the reported state of charge value based on the voltage-based state of charge, the current-based state of charge, and the weight factor.

19. The power management system of claim 14 wherein the battery pack provides electrical power to a motor which is used to drive a vehicle.

20. The power management system of claim 19 wherein the controller is also configured to use the reported state of charge value to control operation of the vehicle, the motor, or the battery pack.
